(19) United States
(12) Patent Application Publication
(10) Pub. No.: US 2009/0302956 A1
(43) Pub. Date: Dec. 10, 2009

(54) Atomic Oscillator

(75) Inventor: Hideyuki Matsuura, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 12/388,628

(22) Filed: Feb. 19, 2009

(30) Foreign Application Priority Data
Jun. 10, 2008 (JP) 2008-151638

(51) Int. Cl. H03L 7/26

(52) U.S. Cl. 331/94.1

(57) ABSTRACT

An atomic oscillator includes a light source, a first coil initiating the light source to emit light, a resonance cell having enclosed atoms absorbing light from the light source, a second coil adjusting the resonant frequency of the atoms in the resonance cell, a resonator supplying the microwave of a predetermined frequency to the resonance cell, a control circuit generating a control voltage corresponding to a light absorption amount in the resonance cell according to the microwave frequency, and an oscillator having an output signal frequency controlled to the resonant frequency by the control voltage, wherein the first and second coils and the resonator are formed of a conductor pattern on a rigid-flexible substrate having a rigid portion and a flexible portion, and the flexible portion is wound on the periphery of the light source and the resonance cell, and connected to a connector disposed on the rigid portion.

### CROSS-REFERENCE TO RELATED APPLICATIONS

This application is based upon and claims the benefit of priority from the prior Japanese Patent Application No. 2008-151638, filed on Jun. 10, 2008, the entire contents of which are incorporated herein by reference.

### FIELD

The present invention relates to a passive atomic oscillator based on the principle of optical pumping.

### BACKGROUND

In recent years, with the advance of information digital networks, a highly accurate and highly stable clock source is essentially required. As such the clock source, an atomic oscillator such as a rubidium atomic oscillator is paid attention to, and a small-sized, low-cost oscillator is desired. In particular, from the viewpoint of mounting on an apparatus, a thin structure is an important issue. To develop a thin atomic oscillator, miniaturization of an optical microwave resonator is a key point (Patent document 1).

FIG. 1 is a diagram illustrating the structure of a rubidium atomic oscillator based on the principle of optical pumping. In FIG. 1, a first magnetic shield structure 101 is covered with a second magnetic shield structure 102. The respective inner sides thereof are covered with heat insulating materials 103, 104. Further, in a resonance cell 105, rubidium atoms are enclosed. Using the transition between the energy levels of the above rubidium atoms, a light of a particular wavelength is absorbed. A photodetector 106 detects light passing through the above resonance cell 105. A cavity resonator 107 houses resonance cell 105, and a coupling antenna 108 supplies a microwave to cavity resonator 107. A solenoid coil 109 generates a static magnetic field to adjust the resonant frequency of the rubidium atoms enclosed in resonance cell 105. A rubidium lamp 110 emits resonance light, and a lamp house 111 houses rubidium lamp 110. An exciter 112 is a circuit for exciting rubidium lamp 110. Also, a coil 113 is provided for discharging rubidium lamp 110 in an electrodeless manner.

An optical microwave unit (OMU) is configured of the above resonance cell 105, photodetector 106, cavity resonator 107, solenoid coil 109, rubidium lamp 110, lamp house 111 and exciter 112. Further, heaters 114, 115 are provided for respectively maintaining resonance cell 105 and rubidium lamp 110 at a constant temperature. Further, there are provided thermistors 116, 117 having resistance values varied with the temperatures of resonance cell 105 and rubidium lamp 110, respectively.

Temperature control circuits 118, 119 are provided for controlling the temperatures of resonance cell 105 and rubidium lamp 110 to be constant. The above temperature control circuits 118, 119 respectively control transistors 120, 121 by the resistance values of thermistors 116, 117, so as to control heater currents.

Moreover, there are provided a preamplifier 122 for amplifying the output of photodetector 106, a low frequency oscillator circuit 123, a synchronous detector circuit 124 for performing synchronous detection of the output of preamplifier 122 using the output of low frequency oscillator circuit 123, a frequency control circuit 125 for controlling a voltage controlled crystal oscillator, which will be described later, by the output of synchronous detector circuit 124, a voltage controlled crystal oscillator 126 for stabilizing the oscillation frequency using atomic resonance produced by resonance cell 105, a frequency modulation circuit 127 modulated by low frequency oscillator circuit 123, and a high frequency generator circuit 128 for generating the resonant frequency (6.8346 . . . GHz) of the rubidium atoms.

FIG. 2 is a diagram illustrating the operating principle of the rubidium atomic oscillator. As illustrated in FIG. 2A, when the rubidium atoms enclosed in resonance cell 105 illustrated in FIG. 1 are in a thermal equilibrium state, the rubidium atoms exist in a (5S, F1) level, which is a ground level, and a (5S, F2) level in equal probability. In the above state, when the resonant light of rubidium lamp 110 is irradiated on resonance cell 105, only the rubidium atoms in the (5S, F1) level are excited to a 5P level, which is called optical pumping, as illustrated in FIG. 2B. However, since the 5P level is an unstable energy level, by spontaneous emission, transition to the (5S, F1) level and the (5S, F2) level occurs with equal probability, as illustrated in FIG. 2C.

Then, after the repetition of the excitation of the rubidium atoms in the (5S, F1) level to 5P by the resonant light of rubidium lamp 110 and the spontaneous emission transition to the (5S, F1) level and the (5S, F2) level with equal probability, the rubidium atoms become existent only in the (5S, F2) level, as illustrated in FIG. 2D. The above state is called a “negative temperature” state. In the above state, a microwave signal generated in high frequency generator circuit 128 is excited in cavity resonator 107. When the microwave signal frequency coincides with a frequency (resonant frequency) corresponding to an energy difference between the (5S, F1) level and the (5S, F2) level, the rubidium atoms in the (5S, F2) level are transited to the (5S, F1) level by stimulated emission, as illustrated in FIG. 2E. At this time, a light level detected by photodetector 106 decreases because resonance cell 105 absorbs light energy emitted from rubidium lamp 110. The transition of the rubidium atoms becomes maximum when the microwave frequency coincides with a frequency (resonant frequency) corresponding to the energy difference between the (5S, F1) level and the (5S, F2) level, and becomes smaller as the difference between the microwave frequency and the resonant frequency becomes greater.

FIGS. 3A and 3B are diagrams illustrating the output of photodetector 106 caused by optical pumping. As illustrated in FIG. 3A, the output of photodetector 106 becomes minimum when the microwave frequency coincides with the resonant frequency, and increases as the difference therebetween becomes greater. Finally, the output becomes constant because the stimulated emission does not occur any more. Additionally, a recess in the vicinity of f₀ of the curve A is called a “dip”.

Now, the output of voltage controlled crystal oscillator 126 is phase modulated by low frequency oscillator circuit 123, and a microwave signal frequency excited in cavity resonator 107 varies accordingly. This causes varied light absorption efficiency (a light absorption amount) in resonance cell 105, and a varied light level detected by photodetector 106. First, when the microwave frequency is equal to f₀, the microwave signal modulated by a low frequency signal varies in the vicinity of the bottom of the dip. As a result, in the output of photodetector 106, a frequency signal having twice as large frequency as the low-frequency modulation frequency is detected, as illustrated by B in FIG. 3A. On the other hand, when the microwave signal is higher than f₀, a microwave signal modulated by the low frequency signal varies in a rise portion of the right side of the dip. As a result, a microwave signal having an identical phase to the low frequency modulation signal is detected, as illustrated by C in FIG. 3A. To the contrary, when the microwave signal is lower than f₀, a microwave signal modulated by the low frequency signal varies in a rise portion of the left side of the dip. As a result, a microwave signal varies with an inverse phase to the low frequency modulation signal, as illustrated by D in FIG. 3A.

Such the above photodetector output is led to a synchronous detector circuit 124 via a preamplifier 122, so that synchronous detection is carried out by means of low frequency oscillator circuit 123. Namely, the output of photodetector 106 amplified by preamplifier 122 is supplied to frequency control circuit 125, and a control voltage (refer to FIG. 3B) to be supplied to voltage controlled crystal oscillator 126 is generated through proportional control, integral control, differential control or control in combination thereof. By the above control voltage, the output of voltage controlled crystal oscillator 126 is controlled to have an identical frequency to the resonant frequency f₀ in the resonance cell. The above output is then supplied to an external circuit, as an output of the rubidium atomic oscillator.

FIG. 4 is a diagram for explaining a structure to assemble an optical-microwave resonator of the rubidium atomic oscillator. The optical-microwave resonator is configured of a rubidium lamp unit P, a cavity resonator unit Q and a heat insulating material unit R.

The rubidium lamp unit P is configured of the following component group: rubidium lamp 110, coil 113 for electrodeless discharge, lamp house 111, heater 115, thermistor 117 for temperature control of the rubidium lamp, coil 113, and rigid substrate 402 supplying necessary power to heater 115. A flexible substrate 403 extends from rigid substrate 402, so as to be connected to a main board. On the main board, there are mounted a variety of control circuits including high frequency generator circuit 128, frequency modulation circuit 127, low frequency oscillator circuit 123, preamplifier 122, synchronous detector circuit 124, frequency control circuit 125 and voltage controlled crystal oscillator 126, and a power supply circuit as well.

Rubidium lamp 110 is adhesively secured inside coil 113 and included in lamp house 111 for heating. To heat lamp house 111, a heater transistor 115 is secured by and in contact with a sheet etc. having good heat conduction.

In the cavity resonator unit Q, cavity resonator 107 is configured of a metal case 405 to be the outer wall of a rectangular waveguide, a metal lid 406 and a rigid substrate 409. Metal case 405 has a light guide hole for guiding an optical pumping light to the inside. A dielectric block 404 to miniaturize the resonator and resonance cell 105 are included inside metal case 405. Further, a heater transistor 114 for heating resonance cell 105 is attached to metal case 405. On the opposite face of the light guide hole, rigid substrate 409 is attached in such a manner as to close an aperture of metal case 405. On rigid substrate 409, there are mounted photodetector 106, thermistor 116 for temperature control and coupling antenna 108 for exciting inside the resonator by microwave. Flexible substrate 403 extends from rigid substrate 409, so as to be connected to the main board.

The upper face of metal case 405 is closed by a metal lid 406. Cavity resonator 107 is formed in the above closed space. On lid 406, a tuning screw 407 is provided for adjusting the resonant frequency of the cavity resonator. By the insertion and extraction of the above tuning screw 407, the resonant frequency is made adjustable. The rubidium lamp unit P and the cavity resonator unit Q are inserted in the heat insulating material unit R, and thereby a heat insulating effect is obtained. The heat insulating material unit R is configured of solenoid coil 109 being wound on the outer periphery of a heat insulating material 410, so as to supply a static magnetic field to the resonance cell. A Zeeman effect produced by the above static magnetic field arranges the energy levels of the rubidium atoms in the resonance cell. Further, by adjusting the applied strength of the static magnetic field, it is possible to adjust the resonant frequency of the rubidium atoms.

FIG. 5 is a top plan view of the optical-microwave resonator formed by the combination of the rubidium lamp unit, the cavity resonator unit and the heat insulating material unit. Since the atomic oscillator based on the optical pumping principle utilizes the Zeeman effect by the static magnetic field, the atomic oscillator is greatly influenced by the static magnetic field of terrestrial magnetism etc. Therefore, the resonance cell is magnetically shielded.

FIG. 6 is an outer schematic view of an optical-microwave resonator covered with a shield case. The optical-microwave resonator is housed in a shield case 601 of a high permeability material. Flexible substrate 403 extending from shield case 601 is connected to a main board 603. Main board 603 is a rigid substrate. On main board 603, there are mounted high frequency generator circuit 128, frequency modulation circuit 127, low frequency oscillator circuit 123, preamplifier 122, synchronous detector circuit 124, frequency control circuit 125, voltage controlled crystal oscillator 126, etc. illustrated in FIG. 1. Further, shield case 601 and main board 603 are housed in an external case (not illustrated), so that a product is completed.

By using the above-mentioned structure, and by optimizing the size and the performance, a rubidium atomic oscillator having a thickness of 18 mm (75 cc in volume) has been developed today.

[Patent document] the official gazette of the Japanese Unexamined Patent Publication No. 2001-308416.

However, in the conventional structure described above, the rubidium atomic oscillator is configured of the combination of a plurality of units, each having a complicated structure also. Such the complicated structure is a cause of impeding further miniaturization and thinner formation. Moreover, the method of assembling each unit is also complicated (particularly, a coil winding process is intricate), and a strict rule is required for the assembly sequence.

### SUMMARY

According to an aspect of the invention, an atomic oscillator includes a light source, a first coil initiating the light source to emit light, a resonance cell having enclosed atoms absorbing light from the light source by transition between energy levels corresponding to a resonant frequency, a second coil adjusting the resonant frequency of the atoms in the resonance cell, a resonator supplying the microwave of a predetermined frequency to the resonance cell by exciting a microwave, a control circuit generating a control voltage corresponding to a light absorption amount in the resonance cell according to the microwave frequency, and an oscillator having an output signal frequency controlled to the resonant frequency by the control voltage, wherein the first coil, the second coil and the resonator are formed of a conductor pattern on a rigid-flexible substrate having a rigid portion and a flexible portion, and the flexible portion is wound on the periphery of the light source and the resonance cell, and connected to a connector disposed on the rigid portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating the structure of a rubidium atomic oscillator based on the principle of optical pumping;

FIG. 2A-E are diagrams illustrating the operating principle of the rubidium atomic oscillator;

FIGS. 3A and 3B are diagrams illustrating the output of photodetector 106 caused by optical pumping;

FIG. 4 is a diagram for explaining a structure to assemble an optical-microwave resonator of the rubidium atomic oscillator;

FIG. 5 is a top plan view of the optical-microwave resonator formed by the combination of the rubidium lamp unit, the cavity resonator unit and the heat insulating material unit;

FIG. 6 is an outer schematic view of an optical-microwave resonator covered with a shield case;

FIGS. 7A, 7B and 7C are diagrams for explaining a structure of the rigid-flexible substrate according to the first embodiment;

FIGS. 8A through 8C are diagrams illustrating the structure of the rigid-flexible substrate according to a second embodiment;

FIGS. 9A through 9C are diagrams illustrating the structure of the rigid-flexible substrate according to the third embodiment;

FIGS. 10A and 10B are diagrams illustrating the structure of the rigid-flexible substrate according to the fourth embodiment; and

FIGS. 11A through 11C are diagrams for explaining the rigid-flexible substrate having the attached shield case.

### DESCRIPTION OF EMBODIMENTS

### First Embodiment

According to a first embodiment, a solenoid coil for discharging a rubidium lamp in an electrodeless manner is formed of a conductor pattern of a rigid-flexible substrate. The rigid-flexible substrate has a flexible substrate and a rigid substrate of an integrated structure. The rigid-flexible substrate is a print substrate including a rigid portion constituted of a hard material such as glass epoxy and a flexible portion using a bendable material. In general, the rigid portion is formed by pasting a glass epoxy substrate on both sides of a portion of the flexible substrate. A portion of the flexible substrate having no glass epoxy substrate pasted thereon becomes the flexible portion intact. Electric conduction between the flexible portion and the rigid portion is secured by through holes.

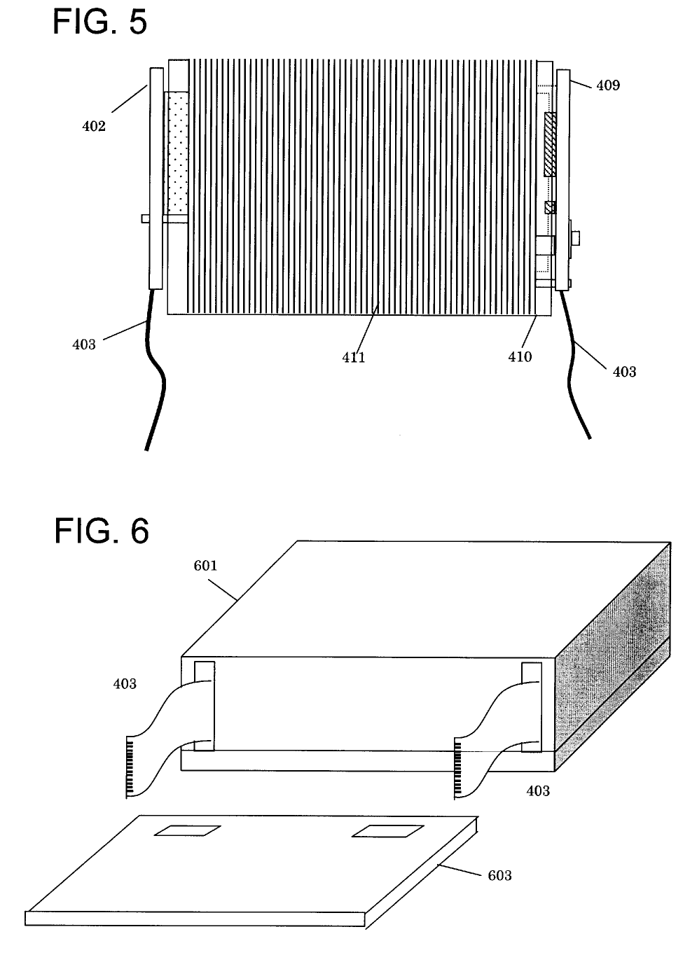

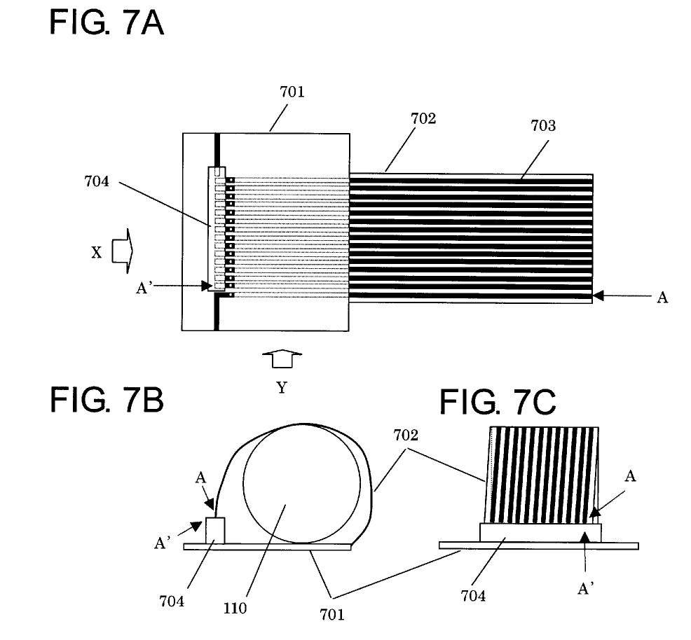

FIGS. 7A and 7C are diagrams illustrating the structure of the rigid-flexible substrate according to the first embodiment.

FIG. 7A is a top plan view of the rigid-flexible substrate. As a conductor pattern, the rigid-flexible substrate includes a plurality of conductor lines 703 extending from a rigid portion 701 toward an end portion A of a flexible portion 702. At the other end A′ of the conductor lines on rigid portion 701, there is provided a connector 704 having each contact point to each of the one end side A of conductor lines 703 on flexible portion 702. For electric connection, the conductor face on the one end side A of conductor lines 703 is exposed on a surface layer.

FIGS. 7B and 7C are diagrams respectively viewed from the directions Y, X illustrated in FIG. 7A. As illustrated in FIG. 7B, flexible portion 702 is looped in a manner to enclose rubidium lamp 110, so that one end side A of conductor lines 703 of flexible portion 702 is connected to connector 704 disposed on the other end side A. At that time, the connection between the one end side A of conductor lines 703 and the other end side A′ thereof via connector 704 is made in a manner to be shifted by one line (refer to FIG. 7C). Thus, a solenoid coil is formed by the plurality of conductor lines 703. The above solenoid coil functions as a coil for the electrodeless discharge of rubidium lamp 110. As such, by looping and connecting to the connector the flexible substrate having the formed conductor pattern, the solenoid coil can be formed easily.

Flexible portion 702 is required to have flexibility to the extent that the loop can be formed. Therefore, preferably, the thickness of the conductor pattern (conductor thickness) on the flexible portion of the rigid-flexible substrate is small. Though products having a variety of thicknesses are commercially sold, products having 18 μm are generally sold as thin products. However, if the conductor thickness is small, a current tolerance value of the conductor becomes small. The excitation circuit current of rubidium lamp 110 is 300 mA maximum, and 100 mA normally. By the size of the conductor thickness of 18 μm with a line width of 0.5 mm, or of that order, it is possible to satisfy both flexibility to be capable of being looped and the condition of the current tolerance value.

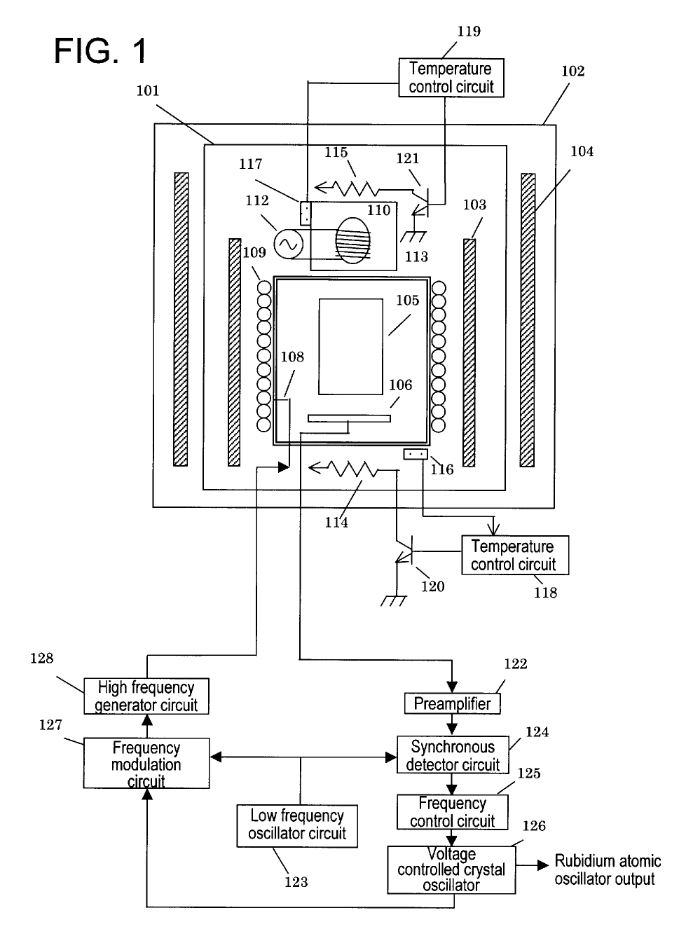

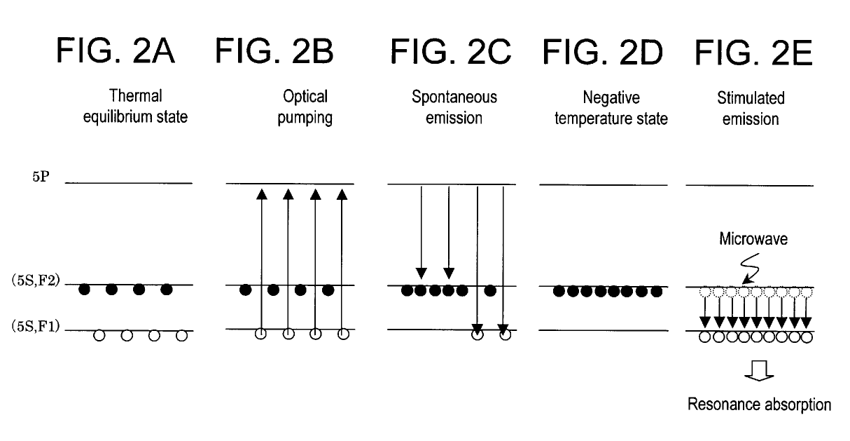

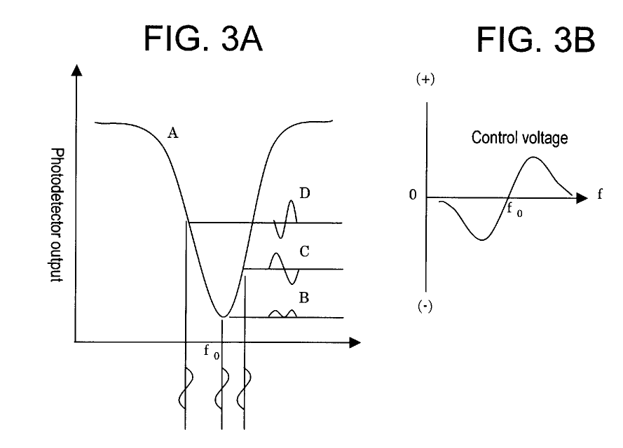

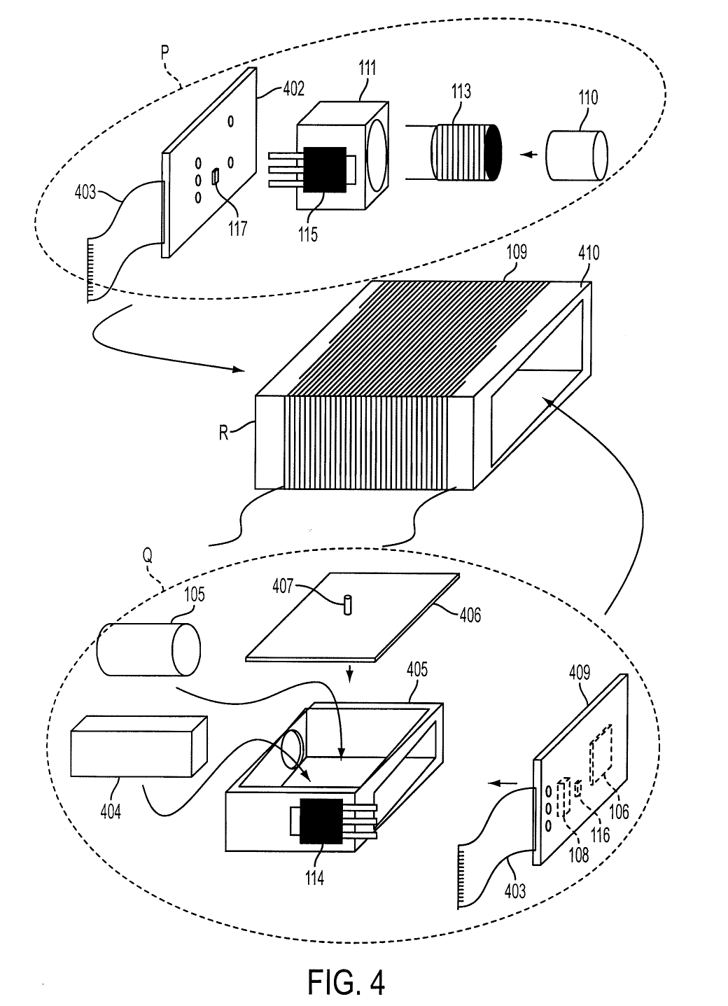

Also, a heater (corresponding to heater 115 illustrated in FIG. 1) and a thermistor (corresponding to thermistor 117 illustrated in FIG. 1) required for heating to vaporize the rubidium in the rubidium lamp can be easily mounted on rigid portion 701. Further, to secure rubidium lamp 110, in consideration of heat conduction, it is preferable to use an adhesive agent having high heat conduction, so as to be filled between with flexible portion 702.

The structure of forming the solenoid coil by looping the flexible portion is also applicable to a solenoid coil to be wound on the periphery of the resonance cell, as will be described later.

### Second Embodiment

According to a second embodiment, a resonator for making a resonance cell resonate is formed using a rigid-flexible substrate.

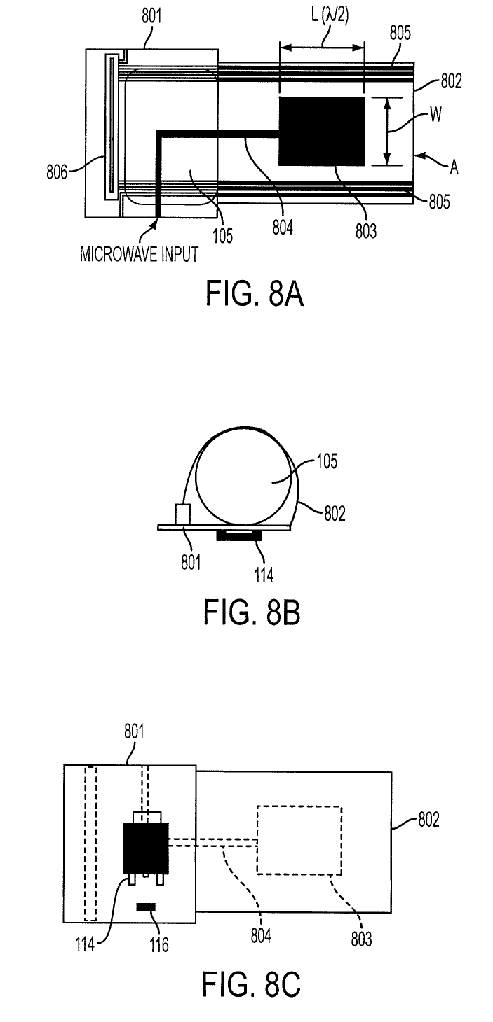

FIGS. 8A through 8C are diagrams illustrating the structure of the rigid-flexible substrate according to a second embodiment. In FIG. 8A, a microstrip line (microstrip resonator) 803 functioning as a resonator is formed on a flexible portion 802 of the rigid-flexible substrate. Microstrip resonator (which is also called patch antenna) 803 has a length L equal to λ/2 (λ is a resonant frequency). In general, the microstrip line produces small leakage of an electromagnetic field. Therefore, by widening a width W of microstrip resonator 803, the leakage of the electromagnetic field is increased, thereby producing magnetic field coupling with the resonance cell. To avoid resonance in an unnecessary mode, preferably, the width W is λ/2 or smaller.

By winding the periphery of resonance cell 105 with flexible portion 802, microstrip resonator 803 is made to contact to the glass surface of resonance cell 105 (refer to FIG. 8B). At this time, microstrip resonator 803 is attached to resonance cell 105 in such a manner that a magnetic field component generated by resonant microstrip resonator 803 becomes parallel to a pumping light.

To microstrip resonator 803, a microstrip line 804 for power feeding is connected, and extends to rigid portion 801. A microwave signal is input from microstrip line 804 on rigid portion 801. The input level of the microwave signal is of the order of −30 dBm, by which the propagation of power through the microstrip line can be made. As such, by configuring the resonator using the conductor pattern, a cavity resonator becomes unnecessary. Thus, the miniaturization and the thin formation of the atomic oscillator can be obtained.

Microstrip lines 803, 804 may be formed on a surface layer, an inner layer or a back surface layer of the rigid-flexible substrate. The ground plane is formed on a different layer from the layer on which microstrip lines 803, 804 are formed. Therefore, at least two layers are necessary.

To realize a microstrip resonator having a resonant frequency of approximately 6834 MHz of the rubidium atom on the flexible portion having at least two layers, in case that a conductor thickness is 18 μm, the thickness of the flexible portion is 25 μm and the dielectric constant is 3.0, the length L of microstrip resonator 803 is L≈15 mm or of that order. Microstrip resonator 803 having the above length is applicable to a resonance cell having a size of φ10×20 mm, although a certain degree of correction is necessary because of the influence of the glass material of resonance cell 105.

Further, in FIG. 8A, the rigid-flexible substrate includes a plurality of conductor lines 805 extending from rigid portion 801 to the end portion A of flexible portion 802. The above plurality of conductor lines 805 are disposed respectively on the upper and lower areas of the portion in which microstrip resonator 803 is formed. Similar to connector 704 illustrated in FIG. 7A, at the other end side A′ of the conductor lines on rigid portion 801, there is provided a connector 806 having each contact point to each end of the one end side A of conductor lines 803 on flexible portion 802.

Further, as illustrated in FIG. 8B, by looping flexible portion 802, the one end side A of conductor lines 805 of flexible portion 802 is connected to connector 806. At that time, the connection between the one end side A of conductor lines 805 and the other end side A′ of the conductor lines via connector 806 is made in a manner to be shifted by one line. Thus, solenoid coils by conductor lines 805 are formed respectively on the upper and lower areas of microstrip resonator 803 in a manner to sandwich microstrip resonator 803. A static magnetic field for inducing the Zeeman effect onto the resonance cell is applied by the solenoid coil formed of conductor lines 805. Additionally, a circuit for applying the static magnetic field using divided solenoid coils is described in the official gazette of the Japanese Unexamined Patent Publication No. 2005-175221, as an example. Also, as described earlier, by looping flexible portion 802 in a manner to enclose the resonance cell, microstrip resonator 803 is made to contact to the glass surface of resonance cell 105.

FIG. 8C is a diagram illustrating the back surface of the rigid-flexible substrate, on which heater 114 and thermistor 116 are mounted. By heating the ground pattern using heater 114, the periphery of resonance cell 105 can be heated effectively. Further, preferably, adhesion between resonance cell 105 and flexible substrate 802 is made by use of an adhesive agent having high heat conduction.

### Third Embodiment

According to a third embodiment, a resonator for making a resonance cell resonate is formed using a rigid-flexible substrate, similar to the second embodiment. In the third embodiment, in place of the microstrip line in the second embodiment, the resonator is formed of a microstrip line.

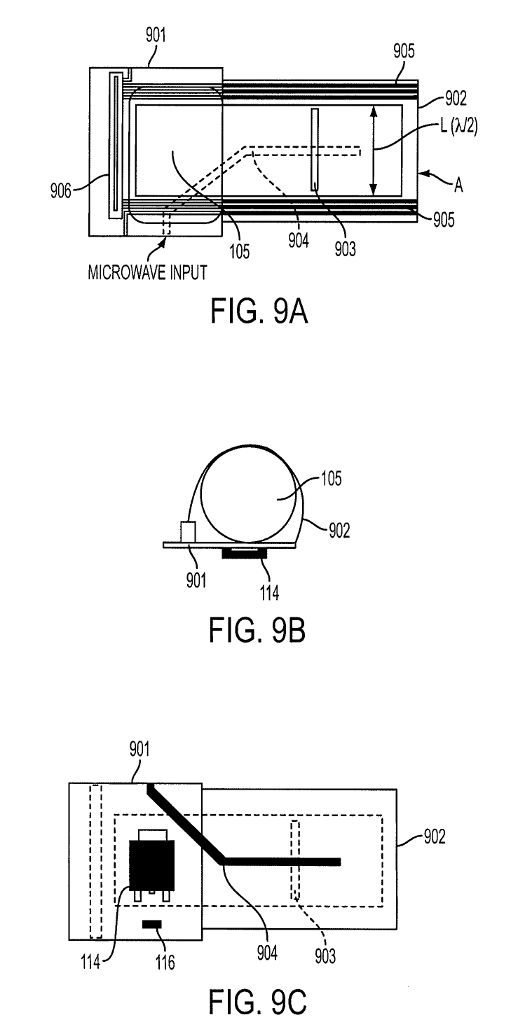

FIGS. 9A through 9C are diagrams illustrating the structure of the rigid-flexible substrate according to the third embodiment. In FIG. 9A, a microslot line (microslot resonator) 903 functioning as a resonator is formed on the surface layer of a flexible portion 902 of the rigid-flexible substrate. The plane on which microslot line 903 is formed becomes a ground plane.

On a layer (inner layer or back surface layer) which is different from the layer having microslot line 903 formed thereon, a microstrip line 904 for power feeding is formed. A microwave signal is input from microstrip line 904, and supplied to microslot line 903. FIG. 9C illustrates a back surface layer of the rigid-flexible substrate, illustrating an example of the formation of microstrip line 904.

Similar to the second embodiment, the periphery of resonance cell 105 is wound with flexible portion 802 so as to make microslot line 903 contact to the glass surface of resonance cell 105 (refer to FIG. 9B). At this time, microslot resonator 903 is attached to resonance cell 105 in such a manner that a magnetic field component generated by resonant microslot resonator 903 becomes parallel to a pumping light.

To realize a microstrip resonator having a resonant frequency of approximately 6834 MHz of the rubidium atom, in case that a conductor thickness is 18 μm, the thickness of the flexible portion is 25 μm, and the dielectric constant is 3.0, the length L of microslot resonator 903 is L≈14 mm or of that order. Microslot resonator 903 having the above length is applicable to a resonance cell having a size of φ10×20 mm, although a certain degree of correction is necessary because of the influence of the glass material of resonance cell 105.

Further, in FIG. 9A, similarly to FIG. 8A, a plurality of conductor lines 905 extending from rigid portion 901 to the end portion A of flexible portion 902 are patterned respectively on the upper and lower areas of the portion of the rigid-flexible substrate in which microstrip resonator 903 is patterned. At the other end side A′ of the conductor lines on rigid portion 901, there is provided a connector 906 having contact points each connected to each end of the one end side A of conductor lines 905 on flexible portion 902.

Further, as illustrated in FIG. 9B, by looping flexible portion 902, the one end side A of conductor lines 905 of flexible portion 902 is connected to connector 906. At that time, the connection between the one end side A of conductor lines 805 and the other end side A′ thereof via connector 906 is made in a manner to be shifted by one line. Thus, solenoid coils by conductor lines 905 are formed respectively on the upper and lower areas of microslot resonator 903 in a manner to sandwich microslot resonator 903. A static magnetic field for inducing the Zeeman effect onto the resonance cell is applied by the solenoid coil. Additionally, as described earlier, by looping flexible portion 902 in a manner to enclose the resonance cell, microslot resonator 903 is made to contact to the glass surface of resonance cell 105.

FIG. 9C is a diagram illustrating the back surface of the rigid-flexible substrate, on which a heater 907 (which corresponds to heater 114 in FIG. 1) and a thermistor 908 (which corresponds to thermistor 116 in FIG. 1) are mounted. By means of heater 907, the ground pattern is heated. Further, preferably, adhesion between resonance cell 105 and flexible substrate 902 is made by use of an adhesive agent having high heat conduction.

### Fourth Embodiment

A fourth embodiment illustrates a structure in which the aforementioned first embodiment and the second embodiment are realized using a single flexible substrate. A solenoid coil for the electrodeless discharge of rubidium lamp 110, a resonator for exciting resonance cell 105, a solenoid coil for supplying a static magnetic field to resonance cell 105 and a peripheral circuit group are formed in an integrated manner. Thus, a simplified structure and easy assembly can be obtained.

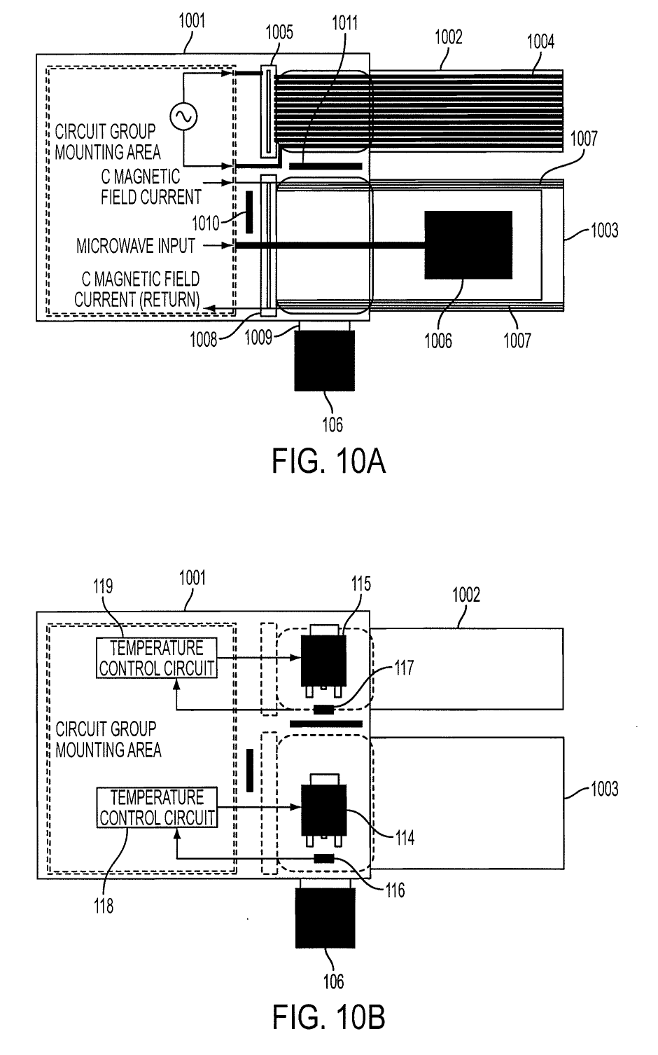

FIGS. 10A and 10B illustrate diagrams illustrating the structure of a rigid-flexible substrate according to the fourth embodiment. FIG. 10A illustrates the surface of the rigid-flexible substrate. The rigid-flexible substrate includes one rigid portion 1001, and two independent flexible portions 1002, 1003 respectively extending from rigid portion 1001. Flexible portion 1002 corresponds to flexible portion 702 in the first embodiment (refer to FIGS. 7A to 7C), and has a plurality of conductor lines 1004 formed in parallel. By looping flexible portion 1002 in a manner to enclose rubidium lamp 110, the end portion of flexible portion 1002 is connected to connector 1005 formed on rigid portion 1001. Thus, a solenoid coil for the rubidium lamp is formed.

Flexible portion 1003 corresponds to flexible portion 802 in the second embodiment (refer to FIGS. 8A to 8C), and has a patterned microstrip resonator 1006. Further, on each of the upper and lower sides thereof, a plurality of conductor lines 1007 are formed in parallel. By looping flexible portion 1003 in a manner to wind resonance cell 105 around, the end portion of flexible portion 1003 is connected to a connector 1008 formed on rigid portion 1001. By this, microstrip resonator 1006 is made to contact to the glass surface of resonance cell 105, and also, solenoid coils for generating static magnetic fields to be applied to resonance cell 105 are formed.

To obtain efficient thermal coupling with rigid portion 1001 and flexible portions 1002, 1003, both rubidium lamp 110 and resonance cell 105 are secured and filled with an adhesive agent having high heat conduction.

Further, rigid portion 1001 includes an area (circuit group mounting area) for mounting a variety of circuit group disposed on the opposite side of an area having the mounted rubidium lamp 110 and resonance cell 105, across sandwich connectors 1005, 1008. Circuits to be mounted include oscillator circuit 112 for high frequency excitation of rubidium lamp 110, high frequency generator circuit 128, preamplifier 122, frequency modulation circuit 127, voltage controlled crystal oscillator 126, low frequency oscillator circuit 123, synchronous detector circuit 124, etc. illustrated in FIG. 1. Instead of the conventional structure having a plurality of rigid substrates connected by flexible substrates, the circuit group can be concentrated on a single rigid-flexible substrate. This contributes to device miniaturization and simplification.

Further, on the back surface of rigid portion 1001, there are mounted heater 115 for heating rubidium lamp 110, thermistor 117 for detecting the temperature of rubidium lamp 110, temperature control circuit 119 of heater 115, heater 114 for heating resonance cell 105, thermistor 116 for detecting the temperature of resonance cell 105, and temperature control circuit 118 for heater 114, as illustrated in FIG. 10B.

Moreover, a photodetector 106 is connected to flexible portion 1009 extending downward from the mounting position of resonance cell 105 on rigid portion 1001. At the time of assembly, photodetector 106 is adhesively secured on the bottom face of resonance cell 105 after flexible portion 1009 is bent.

Holes 1010, 1011 are holes made in rigid portion 1001. As will be described later, hole 1010 is used as an attachment hole for a shield case. Also, because rubidium lamp 110 and resonance cell 105 are normally controlled to different temperatures, hole 1011 is provided to prevent heat conduction therebetween. The reason for separately providing flexible portions 1002, 1003, instead of a single flexible substrate, is to separate thermal coupling also.

In the fourth embodiment illustrated in FIGS. 10A, 10B, an exemplary structure of the first embodiment in combination with the second embodiment has been illustrated. However, it is also possible to configure using the third embodiment (resonator by microslot line), instead of the second embodiment (resonator by microstrip line).

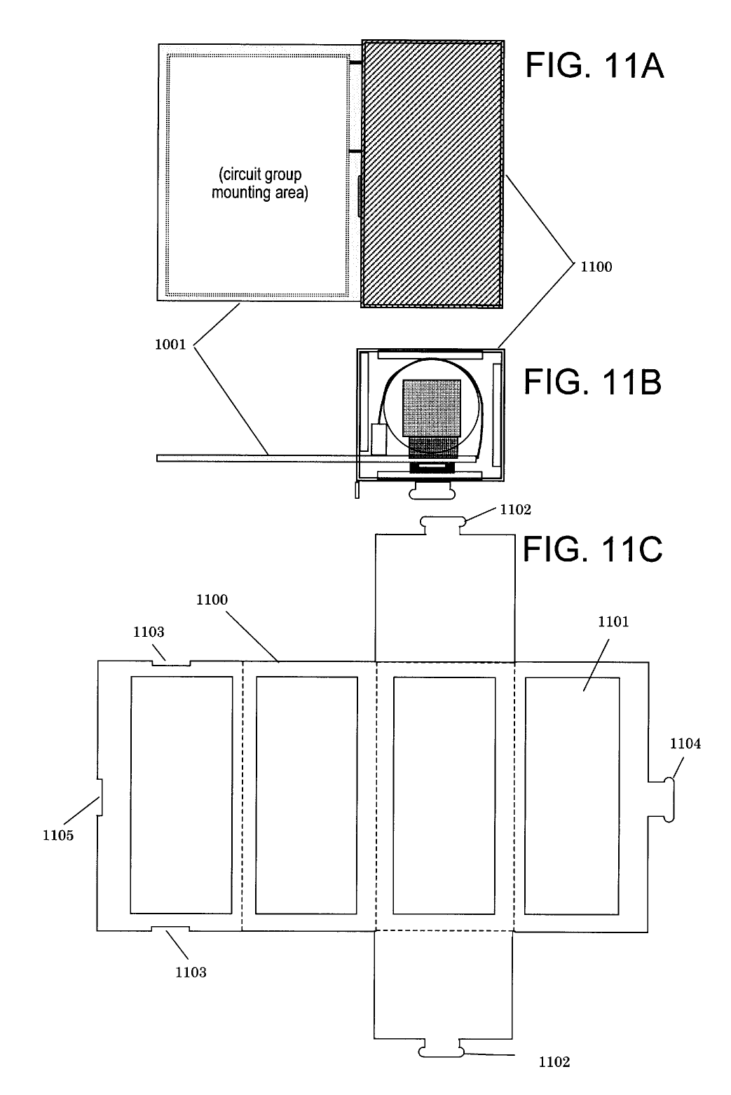

FIGS. 11A through 11C are diagrams for explaining a rigid-flexible substrate on which a shield case is attached. FIGS. 11A-11C illustrate an example in which a shield case 1100 is attached to the rigid-flexible substrate according to the fourth embodiment illustrated in FIGS. 10A, 10B. FIG. 11A is a top plan view of the rigid-flexible substrate having the attached shield case 1100, and FIG. 11B is a section view thereof.

Shield case 1100 is attached in a manner to enclose the disposition portion of the rubidium lamp and the resonance cell on which the flexible portion is wound. With this, shield case 1100 functions as a magnetic shield covering rubidium lamp 110 and resonance cell 105.

FIG. 11C is a development view of shield case 1100. Shield case 1100 is a metal plate of permalloy material. On the inner side of the side face, a resilient heat insulating material 1101 such as urethane is pasted. Heat insulating material 1101 prevents rubidium lamp 110 and resonance cell 105 from directly contacting to the metal plate of shield case 1100, so as to produce loose thermal coupling to the outside.

Further, a protrusion 1102 engages with a recess 1103 at the time of bending to a box shape. Another protrusion 1104 engages with a recess 1105 by being passed through a hole 1011 illustrated in FIG. 10A, at the time of bending to the box shape.

Using the aforementioned structure, basically, an assembly process is completed simply by securing rubidium lamp 110 and resonance cell 105 on predetermined positions of rigid portion 1001, looping flexible portions 1002, 1103 in a manner to be wound on rubidium lamp 110 and resonance cell 105, so as to be connected to connectors 1005, 1008, and covering with shield case 1100. A time and labor consuming wire winding work and a strict assembly rule become unnecessary, and the assembly is completed with an extremely easy work.

According to an aspect of the embodiments, an atomic oscillator has an integrated configuration of a solenoid coil for emitting a rubidium lamp, a solenoid coil for adjusting the resonant frequency of a resonance cell, and a resonator for making the resonance cell resonate, using a conductive pattern formed on a rigid-flexible substrate.

A plurality of conductor lines are formed in parallel on a flexible portion of the rigid-flexible substrate. By looping the flexible portion in a manner to be wound on the rubidium lamp, and by connecting one end of the conductor lines to the other end thereof in a manner to be shifted by one line, there is configured a solenoid coil for the electrodeless discharge of the rubidium lamp.

On the flexible portion of the rigid-flexible substrate, a resonator is formed by a conductor pattern. The flexible portion is looped in a manner to be wound on the resonance cell. The resonator is made to contact to the resonance cell. The conductor pattern is formed of either a microstrip line or a microslot line.

A plurality of conductor lines are formed in parallel respectively on the upper and lower areas of the resonator disposed on the flexible portion. By looping the flexible portion in a manner to be wound on the resonance cell, and by connecting one end of the conductor lines to the other end with a shift by one line, there is configured a solenoid coil for adjusting a resonant frequency of the resonance cell.

By configuring the solenoid coil and the resonator using the conductor pattern formed on the rigid-flexible substrate, an easy-to-assemble atomic oscillator having a simplified structure can be achieved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An atomic oscillator comprising:
a light source;
a first coil initiating the light source to emit light;
a resonance cell having enclosed atoms absorbing light from the light source by transition between energy levels corresponding to a resonant frequency;
a second coil adjusting the resonant frequency of the atoms in the resonance cell;
a resonator supplying the microwave of a predetermined frequency to the resonance cell by exciting a microwave;
a control circuit generating a control voltage corresponding to a light absorption amount in the resonance cell according to the microwave frequency; and
an oscillator having an output signal frequency controlled to the resonant frequency by the control voltage,
wherein the first coil, the second coil and the resonator are formed of a conductor pattern on a rigid-flexible substrate having a rigid portion and a flexible portion, and the flexible portion is wound on the periphery of the light source and the resonance cell, and connected to a connector disposed on the rigid portion.

2. The atomic oscillator according to claim 1,
wherein the control circuit and the oscillator are provided on the rigid portion.

3. The atomic oscillator according to claim 2, further comprising:
a magnetic shield case covering the light source and the resonance cell having the flexible portion wound thereon,
wherein a portion of the rigid portion having the control circuit and the resonance cell disposed thereon is exposed to the outside of the magnetic shield case.

4. The atomic oscillator according to claim 1, further comprising:
a first heater heating the light source and a second heater heating the resonance cell,
wherein the first heater and the second heater are provided on a back surface side of a position of the rigid portion having the light source and the resonance cell contacting thereto.

5. The atomic oscillator according to claim 1,
wherein the resonator is a microstrip resonator.

6. The atomic oscillator according to claim 1,
wherein the resonator is a microslot resonator.

7. An atomic oscillator comprising:
a light source;
a coil initiating the light source to emit light;
a resonance cell having enclosed atoms absorbing light from the light source by transition between energy levels corresponding to a resonant frequency;
a resonator supplying the microwave signal of a predetermined frequency to the resonance cell by exciting a microwave signal;
a control circuit generating a control voltage corresponding to a light absorption amount in the resonance cell according to the microwave signal frequency; and
an oscillator having an oscillation frequency controlled to the resonant frequency by the control voltage,
wherein the coil is formed of a conductor pattern on a rigid-flexible substrate having a rigid portion and a flexible portion, and the flexible portion is wound on the periphery of the light source, and connected to a connector disposed on the rigid portion.

8. An atomic oscillator comprising:
a light source;
a resonance cell having enclosed atoms absorbing light from the light source by transition between energy levels corresponding to a resonant frequency;
a coil adjusting the resonant frequency of the atoms in the resonance cell;
a resonator radiating the microwave signal of a predetermined frequency into the resonance cell by exciting a microwave signal;
a control circuit generating a control voltage corresponding to a light absorption amount in the resonance cell according to the microwave signal frequency; and
an oscillator having an output signal frequency controlled to the resonant frequency by the control voltage,
wherein the coil and the resonator are formed of a conductor pattern on a rigid-flexible substrate having a rigid portion and a flexible portion, and the flexible portion is wound on the periphery of the light source, and connected to a connector disposed on the rigid portion.
